(19) United States
(12) Patent Application Publication
(10) Pub. No.: US 2024/0424514 A1
(43) Pub. Date: Dec. 26, 2024

(54) COOLING DEVICE, METHOD FOR COOLING A COOLING ELEMENT AND LAYER DEPOSITION APPARATUS

(71) Applicant: Leybold GmbH, Cologne (DE)

(72) Inventors: Maik Burkhardt, Cologne (DE); Joergen Koppold, Cologne (DE); Jens Willems, Cologne (DE)

(21) Appl. No.: 18/292,664

(22) PCT Filed: Aug. 5, 2022
(86) PCT No.: PCT/EP2022/072126

§ 371 Date: Jan. 26, 2024

(30) Foreign Application Priority Data
Aug. 6, 2021 (GB) 2111350.1

(51) Int. Cl. B05B 12/12; B05B 1/30; B05B 7/26; C23C 14/50; C23C 14/54; C23C 16/458; C23C 16/46

(52) U.S. Cl. CPC B05B 12/12; B05B 1/3046; B05B 7/267; C23C 14/50; C23C 14/541; C23C 16/4586; C23C 16/463

(57) ABSTRACT

Cooling device, layer deposition apparatus and method for cooling a cooling element. Therein, the cooling device comprises a cooling element having a cooling duct with an inlet and an outlet. With the inlet a compressed gas supply is connected via a supply line. Further a spray supply line is connected to the supply line, wherein a spray nozzle is connected to the spray supply line to nebulize a liquid coolant and feeding the nebulized coolant into the supply line.

### CROSS-REFERENCE OF RELATED APPLICATION

This application is a Section 371 National Stage Application of International Application No. PCT/EP2022/072126, filed Aug. 5, 2022, which is incorporated by reference in its entirety and published as WO 2023/012345 A1 on Feb. 9, 2023, the content of which is hereby incorporated by reference in its entirety and which claims priority of British Application No. GB2111350.1, filed Aug. 6, 2021.

The present invention relates to a cooling device for vacuum apparatus. Further, the present invention relates to a method for cooling a cooling element of a vacuum apparatus. Further, the present invention relates to a layer deposition apparatus comprising such a cooling device.

### BACKGROUND

Common layer deposition apparatus such as atomic layer deposition (ALD) apparatus and physical vaper deposition (PVD) apparatus or the like, comprise a vacuum chamber to maintain a vacuum. In the vacuum chamber a sample holder is disposed holding the substrate or sample during the deposition process. Therein, it is common practice to manipulate the sample during the deposition process such as applying a bias voltage or tilting the sample or heating the sample to high temperatures up to 400° C.

In particular when the sample is heated, it is often necessary for the next step of process or for removing the sample from the apparatus to cool down the sample substantially below temperature of at least 100° C. in order to manually remove the sample or avoid deterioration of the deposited layer during the subsequent step of process.

Therein, immediate opening of the vacuum chamber is not applicable since this would certainly lead to thermal stress in the sample, deteriorate the deposited layer in particular by oxygen in the air reacting with the warm sample and might even be hazardous to the personal due to the high temperatures and the risk to be burned. Thus, it becomes crucial to reduce the temperature of the sample sufficiently in order to avoid the afore-mentioned disadvantages.

However, in the vacuum chamber itself, due to the vacuum, no or only a very little convection is present and can contribute to the cooling of the sample. This leads to very long cool down times up to several hours depending on the starting temperature and/or the desired end temperature. In addition, it is not possible to use a liquid coolant for such high temperatures since the liquid coolant, such as water, will immediately evaporate when coming into contact with the hot sample holder which might lead to damage of the sample holder, the sample or the holder apparatus.

Thus, it is an object of the present invention to provide an improved cooling, thereby reducing the cooling down time of the respective cooling device.

The discussion above is merely provided for general background information and is not intended to be used as an aid in determining the scope of the claimed subject matter. The claimed subject matter is not limited to implementations that solve any or all disadvantages noted in the background.

### SUMMARY

The problem is solved by a cooling device according to claim 1, a method for cooling a cooling element according to claim 9 and a layer deposition apparatus according to claim 15.

In an aspect of the present invention a cooling device for a vacuum apparatus is provided. The cooling device comprises a cooling element having a cooling duct with an inlet and an outlet. With the inlet of the cooling element a supply line is connected. By the supply line a compressed gas supply is connected to the cooling duct of the cooling element. Further, a spray supply line is connected to the supply line, wherein a spray nozzle is connected to the spray supply line or inserted/integrated into the spray supply line to nebulize/atomize a liquid coolant and feeding the nebulized coolant into the supply line.

Thus, by the present invention a compressed gas is used for transporting a nebulized/atomized liquid coolant. By using a nebulized coolant, the heat capacity of the mixture of compressed air and nebulized coolant is increased to provide a sufficient cooling effect to the cooling element. At the same time the amount of liquid coolant is small enough that even under direct evaporation of the nebulized liquid coolant within the cooling element, no damage will be caused to the cooling element or any other element of the vacuum apparatus. Thus, even for high temperatures, efficient cooling can be provided thereby reducing the cool down time compared to convectional cooling down by a factor of 10 or more.

Preferably, the temperature of the cooling element before cooling is above 300° C., more preferably above 400° C. and most preferably above 500° C.

Preferably, the cooling element comprises a resistive heater in order to achieve the high temperate of the cooling element.

Preferably, the cooling element comprises a sample holder or is attached/directly attached to a sample holder of the vacuum apparatus. Alternatively, or additionally the cooling element is built as baffle within the cooling apparatus in order to guide or otherwise affect the deposition process in the vacuum apparatus.

Preferably, the liquid coolant nebulized by the spray nozzle comprises water, glycol or a mixture or water and glycol.

Preferably, the compressed gas is air or nitrogen. Preferably the compressed gas has a pressure between 3 and 8 bar and more preferably between 4 and 6 bar. Therein, the pressure of the compressed gas is below the pressure of the spray supply line.

Preferably, the spray nozzle is a needle valve in order to nebulize the liquid coolant in the spray supply line.

Preferably, the spray supply line has an inlet valve wherein the inlet valve is configured to increase the nebulized liquid coolant with decreasing temperature of the cooling element. Since with decreasing temperature of the cooling element more amount of nebulized liquid coolant can be fed through the cooling duct of the cooling element without adverse effects caused by evaporation when coming into contact with the cooling element, the amount of liquid coolant nebulized by the spray nozzle is increased in order to increase the cooling effect of the cooling element.

Preferably, the pressure of the spray supply line is controllable to be increased with decreasing temperature of the cooling element. In other words, the pressure difference between the spray supply line and the compressed gas is increased in order to increase the amount of nebulized coolant in the mixture of compressed gas and nebulized coolant thereby the cooling effect is further improved if adverse effects caused by the high temperatures of the cooling element are not present.

Preferably, the spray supply line has an inlet valve wherein the inlet valve is configured to increase the duty cycle between an at least partially open position of the inlet valve and a closed position of the inlet valve to increase the nebulized liquid coolant with decreasing temperature of the cooling element. Thus, the inlet valve is opened and closed in short intervals. Therein a full interval of opening and closing the inlet valve is preferably between 0.5 sec and 10 sec, more preferably between 1 sec and 5 sec and most preferably between 2 sec and 3 sec. Therein, for example the inlet valve is at least partially open for a first amount of time if the cooling element has a high temperature and is open for a second amount of time if the temperature of the cooling element is decreasing. Therein the first amount of time is preferably between 0.1 sec and 3 sec, more preferably between 0.2 sec and 2 sec and most preferably between 0.3 sec and 1 sec.

Preferably, the spray nozzle is the inlet valve. Thus, by the spray nozzle itself the amount of nebulized liquid coolant is controlled without the requirement of an additional valve.

Preferably, a coolant supply line is connected to the supply line to supply a liquid coolant to the cooling element. Therein, the coolant supply line comprises a coolant inlet valve configured to open below a threshold temperature and closes above the threshold temperature. Therein by the coolant supply line a liquid coolant can be supplied to the cooling element, if the temperature of the cooling element is below the threshold temperature and prevents feeding a liquid coolant to the cooling element, if the temperature of the cooling element is above the threshold temperature. In particular, the threshold temperature is below the boiling point of the liquid coolant. Therein, in particular, the liquid coolant can be the same liquid coolant being nebulized by the spray nozzle or can be a different liquid coolant.

Thus, by the cooling device according to the present invention liquid coolant is nebulized or atomized and provided to a cooling element together with and conveyed by the compressed gas from the compressed gas supply. Thus, by the mixture of nebulized coolant and compressed gas, efficient cooling of the cooling element is provided reducing the cool down time of the cooling element.

In an aspect of the present invention a method for cooling a cooling element of a vacuum apparatus is provided. The method comprises the steps of:
Providing compressed gas to the cooling element and;
Providing a nebulized liquid coolant to the cooling element by the compressed gas.

Thus, by the stream of compressed gas the nebulized liquid coolant is transported to the cooling element and is there cooling down the cooling element even from high temperatures above preferably 300° C., more preferably above 400° C. and most preferably above 500° C.

Preferably, the amount of nebulized coolant is increased with decreasing temperature of the cooling element. Thus, with decreasing temperature of the cooling element, the amount of nebulized coolant in the stream of compressed gas and nebulized coolant is increased, increasing the cooling efficiency of the cooling element.

Preferably, the pressure of liquid coolant to be nebulized is increased with decreasing temperature of the cooling element. Thus, more liquid coolant is nebulized and provided to the cooling element.

Preferably, an inlet valve of a spray supply line providing the nebulized coolant is opened further with decreasing temperature of the cooling element in order to increase the amount of nebulized coolant with decreasing temperature of the cooling element.

Preferably, an inlet valve of a spray supply line is opened longer in a duty cycle with decreasing temperature of the cooling element. Thus, in a duty cycle of an at least partially opened inlet valve and a closed inlet valve, the amount of times for the at least partially opened inlet valve is increased in order to increase the amount of liquid coolant to be nebulized and fed to the cooling element.

Preferably, below a threshold temperature of the cooling element a liquid coolant is provided to the cooling element wherein in particular the threshold temperature is below the boiling point of the liquid coolant. Thus, as soon as the cooling element has a temperature which does not evaporate the liquid coolant, liquid coolant can be supplied to the cooling element without damage of the cooling element or vacuum apparatus.

Preferably, the method is further built along the features of the cooling device described above.

Preferably, the method is implemented in a cooling device described above.

In an aspect of the present invention, a layer deposition apparatus is provided comprises a vacuum chamber, a sample and a sample holder disposed in the vacuum chamber. Further, the layer deposition apparatus comprises a deposition module in order to deposition material on the sample held by the sample holder. Therein, the sample holder comprises a cooling device according to the cooling device described above. In particular, the sample holder is built as one piece with the cooling device or is directly attached to the cooling device.

Preferably, the layer deposition apparatus is an atomic layer deposition apparatus or a physical vapor deposition apparatus or the like.

Preferably, the layer deposition apparatus is built along the features as described in connection with the cooling device above.

Preferably, the method described above is implemented in such a layer deposition apparatus.

The Summary is provided to introduce a selection of concepts in a simplified form that are further described in the Detail Description. This summary is not intended to identify key features or essential features of the claimed subject matter, nor is it intended to be used as an aid in determining the scope of the claimed subject matter.

### DESCRIPTION OF THE DRAWINGS

In the following the present invention is described in more detail with reference to the accompanying figures.

The figures show:

FIG. 1 a cooling device according to the present invention and

FIG. 2 a detail of controlling the cooling device according to the present invention.

### DETAILED DESCRIPTION

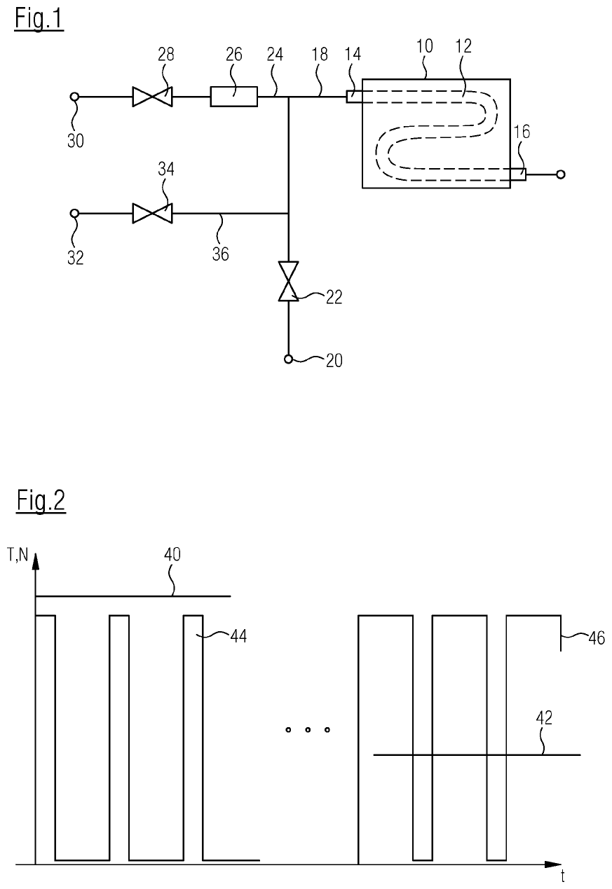

Referring to FIG. 1 showing a cooling device according to the present invention. The cooling device comprises a cooling element 10 which might be built as sample holder or baffle and disposed within a vacuum chamber of a vacuum apparatus. Alternatively, the cooling element 10 might be directly attached to a sample holder or baffle of the vacuum apparatus. The cooling element 10 comprises a cooling duct 12 having an inlet 14 and an outlet 16. The cooling duct 12 is running through the cooling element 10 in order to provide sufficient heat transfer from the cooling element 10 to the coolant provided to the cooling duct 12.

To the inlet 14 of the cooling duct 12 a supply line 18 is connected. The supply line 18 is connected to a compressed gas supply 20 via a compressed gas inlet valve 22. Thus, compressed gas from compressed gas supply is fed through the cooling duct 12 via the supply line 18 wherein the amount of compressed gas is controlled by the compressed gas inlet valve 22.

To the supply line 18 a spray supply line 24 is connected wherein a spray nozzle 26 is connected to the spray supply line or integrated into the spray supply line. By the spray nozzle 26 a liquid coolant provided by a liquid coolant supply 30 is nebulized or atomized and fed as mist or fog through the spray supply line into the supply line 18 and into the cooling duct 12 conveyed by the stream of compressed gas. Therein, an inlet valve 28 is disposed in the spray supply line 24. In the example of FIG. 1, the inlet valve 28 and the spray nozzle 26 are illustrated as two separate elements. However, the spray nozzle 26 can at the same time serve as inlet valve 28 integrating both functions. In particular, the spray nozzle 26 is built as needle valve. By the inlet valve 28 the amount of liquid coolant fed to the spray nozzle 26 or the amount of nebulized coolant provided to the cooling element 10 via the spray supply line 24 and the supply line 18 can be controlled and adjusted.

In an embodiment exemplified in FIG. 1, the cooling device might have further a coolant supply line 36 connected to a liquid coolant supply 32 in order to provide a liquid coolant to the cooling element 10. Therein, the coolant supply line 36 comprises a coolant inlet valve 34 in order to control whether liquid coolant is supplied from the liquid coolant 32 to the cooling element 10. However, the coolant supply line 36 is an optional feature. Thus, if the temperature of the cooling element 10 drops below a certain temperature threshold, the inlet valve 28 is closed, the compressed gas inlet valve 22 and the coolant inlet valve 34 is opened to supply a liquid coolant to the cooling element 10. Therein, the temperature threshold is below 100° C. and preferably 80° C. Thus, by use of a liquid coolant for lower temperatures of the cooling element 10, cooling efficiency can be further increased, decreasing cool down times further.

Further, the cooling element might comprise a heater or is directly connected to a heater in order to heat up the sample holder or the baffle. Preferably the heater is built as a resistive heater and is configured to heat up the sample holder or baffle to a temperature above 300° C., more preferably above 400° C. and most preferably above 500° C.

If then the sample is heated up to such high temperatures and in a next step low temperatures are required in the process of layer deposition or the sample shall be removed from the deposition apparatus, the sample must be cooled down. Therein, immediate venting of the vacuum chamber might lead to deteriorating the deposited layer. On the other hand, convectional cooling is inefficient in vacuum and requires a huge amount of time.

Thus, in accordance with the present invention and in particular in accordance to the method for cooling the cooling element, if the cooling element 10 is at high temperatures a compressed gas is provided to the cooling element 10 from the compressed gas supply 20 by opening the compressed gas inlet valve 22. At the same time the inlet valve 28 in the spray supply line 24 is at least partially opened such that liquid coolant from the liquid coolant supply 30 is nebulized/atomized by the spray nozzle 26 and then conveyed by the compressed gas through the cooling duct 12 of the cooling element. By the nebulized coolant a heat capacity of the mixture of compressed gas and nebulized coolant is increased improving the cooling effect and thereby reducing the cool down times of the cooling element 10 by a factor up to 10.

Therein, the temperature of the cooling element 10 might be detected and the amount of nebulized coolant is increased with decreasing temperature of the cooling element 10 by control of the inlet valve 28 and/or control of the compressed gas inlet valve 22. For lower temperatures immediate evaporation of the nebulized coolant is reduced thereby reducing the possibility of damages to the cooling element 10 and at the same time increasing the cooling efficiency of the cooling element 10.

Preferably, in order to increase the amount of nebulized coolant, the pressure of the liquid coolant provided by the liquid coolant supply 30 connected to the spray supply line 24 might be increased thereby increasing the amount of nebulized coolant in the stream of compressed gas and nebulized coolant. At the same time or alternatively, the pressure of the provided compressed air can be reduced preferably by the compressed gas inlet valve 22 in order to increase the difference between the pressures of the spray supply line and the compressed gas supply, thereby increasing the amount of nebulized coolant fed to the supply line 24.

Preferably, the amount of nebulized coolant is increased by further opening the at least partially opened inlet valve 28 in the spray supply line 24, increasing the amount of nebulized coolant provided to the cooling element 10.

Preferably, the inlet valve 28 is opened and closed periodically wherein one period of opening and closing may have a time of between 0.5 sec and 10 sec, more preferably between 1 sec and 5 sec and most preferably between 2 sec and 3 sec. The situation is depicted in FIG. 2 showing the temperature 40 for a high temperature section and the temperature 42 for a low temperature section. Signal 44 shows the control signal of the inlet valve 28 for the high temperature section wherein visibly the inlet valve 28 is open for a short amount of time of the overall period. Thus, the duty cycle is small. Therein, preferably the opening times of the inlet valve 28 are between 0.1 sec and 3 sec, more preferably between 0.2 sec and 2 sec and most preferably between 0.3 sec and 1 sec. If the temperature decreases overtime, more nebulized coolant can be fed to the cooling element 10. Thus, the duty cycle is increased as indicated by the control signal 46 for lower temperatures 42 depicted in FIG. 2 leading to an increased amount of nebulized coolant provided to the cooling element further improving the cooling efficiency of the cooling device. Therein, adjustment of the duty cycle can be performed stepwise or continuously in dependence on the temperature of the cooling element 10. Therein, opening times of the inlet valve might be calculated by

$${t}_{open} [ s ] = {t}_{start} [ s ] + ( {t}_{period} [ s ] - 2 * {t}_{start} [ s ] ) * ( {T}_{init} [ ° C . ] - {T}_{act} [ ° C . ] ) / ( {T}_{init} [ ° C . ] - {T}_{dest} [ ° C . ] )$$

$$and$$

$${t}_{close} [ s ] = {t}_{period} [ s ] - {t}_{open} [ s ] ,$$

wherein t_{period} is the total period time of the valve duty cycle, tₒₚₑₙ is the valve opening time, t_{close} is the valve closing time, tₛₜₐᵣₜ is the valve start opening time at the beginning of the cooling, Tᵢₙᵢₜ is the initial heating temperature, T_{dest} is the destination cool down temperature and T_{act} is the actual temperature of the cooling element.

Therein, start time might be between 0.1 sec and 3 sec, more preferably between 0.2 sec and 2 sec and most preferably between 0.3 sec and 1 sec as indicated above. Initial temperature denotes the temperature of the cooling element 10 before cooling or at the beginning of the cool down process, and actual temperature denotes the current temperature of the cooling element 10. Period time denotes the length of a complete opening-closing cycle of the inlet valve 28 and might be between 0.5 sec and 10 sec, more preferably between 1 sec and 5 sec and most preferably between 2 sec and 3 sec.

Thus, for a specific example t_{period} is set to be 2.8 s, tₛₜₐᵣₜ is set to be 0.3 s, Tᵢₙᵢₜ is set to be 300° C., T_{dest} is set to be 80° C., then the valve opening times and valve closing times calculate to:

$${t}_{open} [ s ] = 0.3 s + ( 300 °C . - {T}_{act} [ ° C . ] ) * s / 100 °C .$$

$$and$$

$${t}_{close} [ s ] = 2.8 s - {t}_{open} [ s ] ,$$

and thus, at the beginning of the cooling down procedure with T_{act}=Tᵢₙᵢₜ=300° C., the valve opening time and the valve closing time yields to tₒₚₑₙ=0.3 s, t_{close}=2.5 s. Upon reaching the destination cool down temperature with T_{act}=T_{dest}=80° C., the valve opening time and the valve closing time yields to tₒₚₑₙ=2.5 s, t_{close}=0.3 s.

Thus, by the present invention efficient cooling of a cooling element is provided by utilizing the increased heat capacity of a nebulized liquid coolant conveyed by a steam of compressed air to the cooling element 10. In order to further increase the cooling efficiency at decreasing temperatures, the amount of nebulized coolant fed to the cooling element is increased. As soon as the temperature of the cooling element 10 is below a temperature threshold, it is not necessary anymore to provide the coolant in a nebulized form and thus a liquid coolant is provided to the cooling element 10 in order to further enhance the cooling efficiency of the cooling element and provide cool downs up to 10 times shorter than of common cooling devices.

Although elements have been shown or described as separate embodiments above, portions of each embodiment may be combined with all or part of other embodiments described above.

Although the subject matter has been described in language specific to structural features and/or methodological acts, it is to be understood that the subject matter defined in the appended claims is not necessarily limited to the specific features or acts described above. Rather, the specific features and acts described above are described as example forms of implementing the claims.

1. A cooling device for a vacuum apparatus comprising:
a cooling element having a cooling duct with an inlet and an outlet,
wherein the inlet is connected to a compressed gas supply via a supply line,
a spray supply line connected to the supply line, wherein a spray nozzle is connected to the spray supply line to nebulize a liquid coolant and feeding the nebulized coolant into the supply line.

2. The cooling device according to claim 1, wherein the cooling element comprises a sample holder or is built as baffle.

3. The cooling device according to claim 1, wherein the spray nozzle is a needle valve.

4. The cooling device according to claim 1, wherein the spray supply line has inlet valve, wherein the inlet valve is configured to increase the nebulized liquid coolant with decreasing temperature of the cooling element.

5. The cooling device according to claim 1, wherein the pressure of the spray supply line is controllable to be increased with decreasing temperature of the cooling element.

6. The cooling device according to claim 1, wherein the spray supply line has an inlet valve, wherein the inlet valve is configured to increase the duty cycle between an at least partially open position of the inlet valve and a closed position of the inlet valve to increase the nebulized liquid coolant with decreasing temperature of the cooling element.

7. The cooling device according to claim 4, wherein the spray nozzle is the inlet valve.

8. The cooling device according to claim 1, wherein a coolant supply line is connected to the supply line to supply a liquid coolant the cooling element, wherein the coolant supply line comprises a coolant inlet valve configured to open at a temperature of the cooling element below a threshold temperature and close at a temperature of the cooling element above the threshold temperature, wherein preferably the threshold temperature is below the boiling point of the liquid coolant.

9. A method for cooling a cooling element of a vacuum apparatus comprising:
Providing compressed gas to the cooling element; and
Providing a nebulized liquid coolant to the cooling element by the compressed gas.

10. The method according to claim 9, wherein the amount of nebulized coolant is increased with decreasing temperature of the cooling element.

11. The method according to claim 10, wherein the pressure of liquid coolant to be nebulized is increased with decreasing temperature of the cooling element.

12. The method according to claim 10, wherein an inlet valve of a spray supply line is opened further with decreasing temperature of the cooling element.

13. The method according to claim 10, wherein an inlet valve of a spray supply line is opened longer in a duty cycle with decreasing temperature of the cooling element.

14. The method according to claim 9, wherein below a threshold temperature of the cooling element a liquid coolant is provided to the cooling element, wherein preferably the threshold temperature is below the boiling point of the liquid coolant.

15. A layer deposition apparatus comprising a vacuum chamber, a sample holder disposed in the vacuum chamber and a deposition module, wherein the sample holder comprises a cooling device according to claim 1.
